(19) United States
(12) Patent Application Publication
(10) Pub. No.: US 2020/0313021 A1
(43) Pub. Date: Oct. 1, 2020

(54) PHOTODETECTOR

(71) Applicant: PHOTONICS ELECTRONICS TECHNOLOGY RESEARCH ASSOCIATION, Tokyo (JP)

(72) Inventor: Junichi Fujikata, Tokyo (JP)

(21) Appl. No.: 16/817,152

(22) Filed: Mar. 12, 2020

(30) Foreign Application Priority Data
Mar. 27, 2019 (JP) 2019-060316

(51) Int. Cl. H01L 31/105; H01L 31/0352; H01L 31/0232

(52) U.S. Cl. CPC H01L 31/105; H01L 31/02327; H01L 31/03529

(57) ABSTRACT

A photodetector which can perform high-speed operation and make the manufacturing process thereof easy is provided. A photodetector 400 comprises an Si layer including a lateral pin junction structure, and a light absorbing layer stacked on the lateral pin junction structure. At least part of an upper part of the light absorbing layer is doped to exhibit a first conductivity type. At least part of a side wall of the light absorbing layer is doped to exhibit the first conductivity type, for making the at least part of the upper part of the light absorbing layer to be electrically connected to a region of the first conductivity type in the lateral pin junction structure.

### TECHNICAL FIELD

The present invention relates to a photodetector.

### BACKGROUND ART

It becomes possible to achieve integration of an optical function element and an electronic circuit on a silicon platform, by using a silicon-photonics technique. This is a very potential technique expected to be used for realizing optical communication devices used in various kinds of application.

A silicon-based optical device, which uses a lateral pin junction structure, has been suggested. For example, Patent Literature 1 discloses an electric-field-absorption optical modulator which comprises a first Si layer of a first conductivity type and a second Si layer of a second conductivity type which are positioned in parallel with a substrate, and a GeSi layer stacked on the above layers.

### CITATION LIST

### Patent Literature

PTL 1: Japanese Parent Application Public Disclosure No. 2019-008163

### SUMMARY OF INVENTION

### Technical Problem

An object of the present disclosure is to provide a photodetector which can perform high-speed operation and make the manufacturing process thereof easy.

### Solution to Problem

According to an embodiment of the present disclosure, a photodetector is provided, the photodetector being characterized in that: the photodetector comprises an Si layer including a lateral pin junction structure, and a light absorbing layer stacked on the lateral pin junction structure; wherein at least part of an upper part of the light absorbing layer is doped to exhibit a first conductivity type, and at least part of a side wall of the light absorbing layer is doped to exhibit the first conductivity type, for making the at least part of the upper part of the light absorbing layer to be electrically connected to a region of the first conductivity type in the lateral pin junction structure.

In an example, an i region in the lateral pin junction structure is arranged in a position offset from a center of the light absorbing layer in a lateral direction, toward the first-conductivity-type region in the lateral pin junction structure.

In an example, the photodetector comprises metal electrodes that are electrically connected to a region, that has been high-concentration-doped to exhibit the first conductivity type, in the Si layer and a region, that has been high-concentration-doped to exhibit a second conductivity type, in the Si layer, respectively.

In an example, the light absorbing layer has a layered structure comprising a GeSi layer and an Si cap layer.

In an example, at least part of the light absorbing layer is buried in the Si layer.

In an example, in an interface between the light absorbing layer and the lateral pin junction structure, the light absorbing layer is doped to exhibit the first conductivity type or the second conductivity type.

In an example, the lateral pin junction structure comprises at least one pin junction.

In an example, the light absorbing layer comprises a compound semiconductor.

In an example, the light absorbing layer is optically coupled to an optical waveguide formed by the Si layer, and is configured to receive an optical signal from the optical waveguide.

In an example, the photodetector receives an optical signal directed toward the light absorbing layer from up above or down below the light absorbing layer.

In an example, the light absorbing layer has a thickness that has been set for improving a light absorption ratio by optical resonance effect (Fabry-Perot effect) in the light absorbing layer.

In an example, the lateral pin junction structure and the light absorbing layer form a rib-shaped waveguide structure.

In an example, the first conductivity type is a p type or an n type.

In an example, the Si layer is formed on a buried oxide film layer stacked on an Si substrate.

### Advantageous Effects of Invention

According to the present disclosure, a photodetector which can perform high-speed operation and make the manufacturing process thereof easy can be provided.

### BRIEF DESCRIPTION OF DRAWINGS

FIG. 1 schematically shows a cross-section view of a prior-art photodetector.

FIG. 2 is a graph showing a characteristic of high-speed operation of the photodetector in FIG. 1, that is obtained by performing simulation.

FIG. 3 shows result of simulation, with respect to optical electric field intensity distribution, in the photodetector in FIG. 1.

FIG. 4 schematically shows a cross-section view of a photodetector according to an embodiment of the present disclosure.

FIG. 5 shows result of simulation, with respect to optical electric field intensity distribution, in the photodetector in FIG. 4.

FIG. 6A is a figure for explaining a method for manufacturing a photodetector according to an embodiment of the present disclosure.

FIG. 6B is a figure for explaining the method for manufacturing the photodetector according to the embodiment of the present disclosure.

FIG. 6C is a figure for explaining the method for manufacturing the photodetector according to the embodiment of the present disclosure.

FIG. 6D is a figure for explaining the method for manufacturing the photodetector according to the embodiment of the present disclosure.

FIG. 6E is a figure for explaining the method for manufacturing the photodetector according to the embodiment of the present disclosure.

FIG. 6F is a figure for explaining the method for manufacturing the photodetector according to the embodiment of the present disclosure.

FIG. 6G is a figure for explaining the method for manufacturing the photodetector according to the embodiment of the present disclosure.

FIG. 6H is a figure for explaining the method for manufacturing the photodetector according to the embodiment of the present disclosure.

FIG. 6I is a figure for explaining the method for manufacturing the photodetector according to the embodiment of the present disclosure.

FIG. 6J is a figure for explaining the method for manufacturing the photodetector according to the embodiment of the present disclosure.

FIG. 7 schematically shows a cross-section view of a photodetector according to an embodiment of the present disclosure.

FIG. 8 shows result of simulation, with respect to quantum efficiency, in the photodetector in FIG. 7.

### DESCRIPTION OF EMBODIMENTS

In the following description, embodiments of the present disclosure will be explained in detail, with reference to the figures.

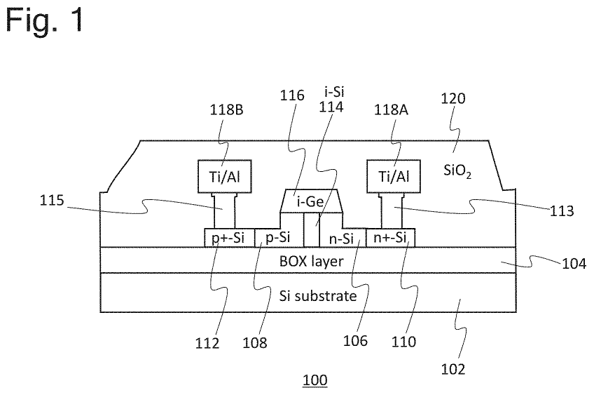

FIG. 1 schematically shows a cross-section view of a prior-art photodetector. A photodetector 100 comprises a silicon (Si) substrate 102, and a buried oxide film layer (BOX layer) 104 comprising silica glass (SiO₂) stacked on the Si substrate 102. The photodetector 100 also comprises an Si layer stacked on the BOX layer 104. The Si layer includes a lateral pin junction structure which comprises Si and is formed in a lateral direction with respect to the Si substrate 102 (a direction parallel to the Si substrate 102). The lateral pin junction structure comprises a first-conductivity-type region (hereinafter, this is also referred to as an “n-Si region”) 106 that has been doped to exhibit a first conductivity type (an n type herein), a second-conductivity-type region (hereinafter, this is also referred to as a “p-Si region”) 108 that has been doped to exhibit a second conductivity type (a p type herein), and an intrinsic Si region (hereinafter, this is also referred to as an “i-Si region”) 114 positioned between the n-Si region 106 and the p-Si region 108.

The photodetector 100 further comprises a light absorbing layer stacked on the lateral pin junction structure. In this example, the light absorbing layer comprises an intrinsic germanium (Ge) region (hereinafter, this is also referred to as an “i-Ge layer”) 116. In the lateral pin junction structure, the i-Si region 114 is arranged in a position that approximately coincides with that in the center of the i-Ge layer 116 in a lateral direction.

The Si layer stacked on the BOX layer 104 further comprises a region (hereinafter, this is also referred to as an “n+-Si region”) 110 that has been high-concentration-doped to exhibit the first conductivity type (an n type herein), and a region (hereinafter, this is also referred to as a “p+-Si region”) 112 that has been high-concentration-doped to exhibit the second conductivity type (a p type herein). The n+-Si region 110 is connected to a metal electrode 118A via a wiring line 113. The p+-Si region 112 is connected to a metal electrode 118B via a wiring line 115. The metal electrodes 118A and 118B may comprise Ti/Al, for example. The photodetector 100 further comprises a cladding layer 120 which comprises Sift stacked on the above-explained respective components. The above-explained photodetector 100 can be constructed by using a silicon photonics technique.

The inventor of the subject application has performed simulation for verifying performance of the prior-art photodetector 100 shown in FIG. 1.

Main numerical values used in the simulation are as follows:

Width of n-Si region 106: 1000 nm

Width of p-Si region 108: 1000 nm

Width of i-Si region 114: 300 nm

Width of n+-Si region 110: 2000 nm

Width of p+-Si region 112: 2000 nm

Width of bottom face of i-Ge layer 116: 600 nm

Thickness of p+-Si region 112 and n+-Si region 110: 90 nm

Distance between upper face of BOX layer 104 and lower face of i-Ge layer 116: 200 nm

Thickness of i-Ge layer 116:: 300 nm

Doping concentration in n-Si region 106: 1*10¹⁹/cm³

Doping concentration in p-Si region 108: 1*10¹⁹/cm³

Doping concentration in n+-Si region 110: 2*10²¹/cm³

Doping concentration in p+-Si region 112: 2*10²¹/cm³

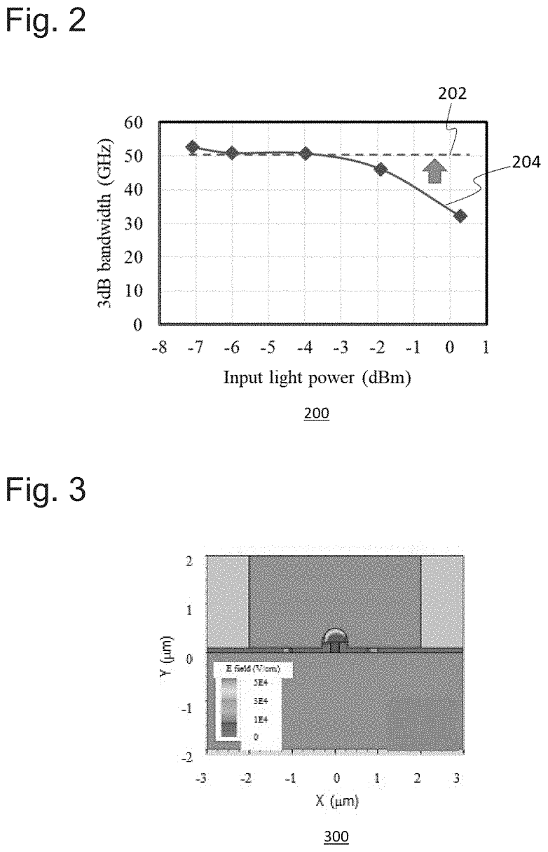

FIG. 2 is a graph showing a characteristic of high-speed operation of the photodetector 100, that is obtained by performing simulation. The horizontal axis of the graph 200 represents input light power to the photodetector 100. The vertical axis of the graph 200 represents a 3 dB bandwidth in the frequency characteristic of an output signal of the photodetector 100. It is desirable that the photodetector 100 be able to be used in various kinds of application such as that in short-range optical communication within a data center wherein it is assumed that input light power is low, middle/long-range optical communication wherein it is assumed that input light power is much higher, and so on. Thus, it is ideal that the photodetector 100 has a characteristic such as that represented by a dashed line 202.

As would be understood from a solid line 204 which represents result of the simulation, in the case that the value of input light power is relatively small, such as −4 dBm or a value close thereto, the 3dB bandwidth with respect to the photodetector 100 does not deteriorate, so that sufficient high-speed operation can be performed. However, regarding the 3dB bandwidth, although the maximum value with respect thereto is approximately 50 GHz, it is decreased to approximately 30 GHz, when the input light power is increased to 0 dBm or a value close thereto.

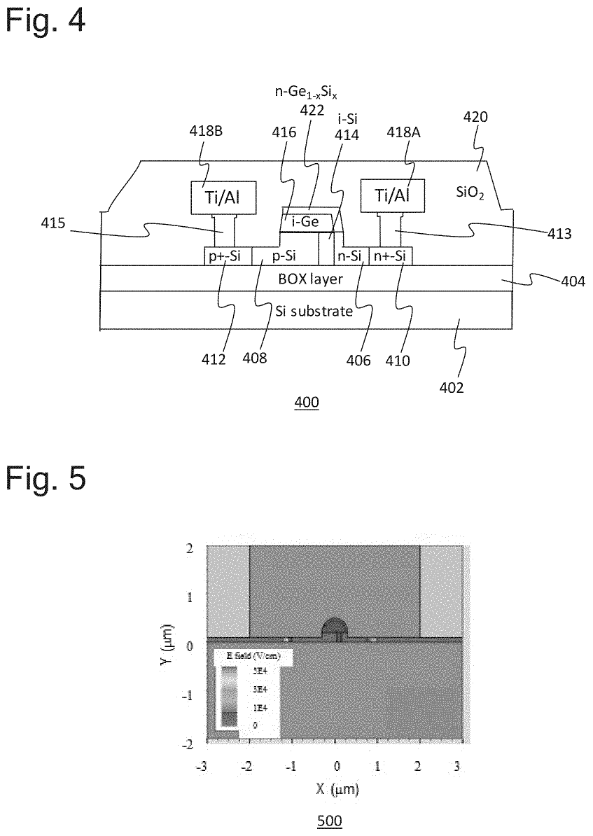

FIG. 3 shows result of simulation, with respect to optical electric field intensity distribution, in the photodetector 100, in the case that the input light power is set to 0 dBm. It can be understood that, in at least part of the light absorbing layer, the value of the optical electric field intensity is decreased to that lower than the maximum value.

Based on the above computation result, the inventor of the subject application has obtained information that, in the case of the prior-art photodetector 100, the high-speed operation characteristic deteriorates when the input light power is increased to approximately 0 dBm.

Based on the above information, the inventor of the subject application has invented a photodetector having a novel structure which allows high-speed operation even if the input light power is increased, and makes the manufacturing process thereof easy. In the following description, photodetectors according to embodiments of the present disclosure will be explained.

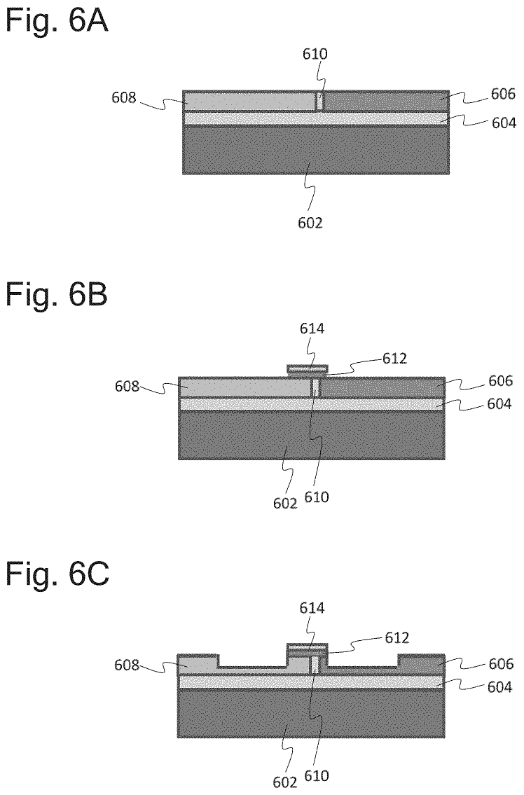

FIG. 4 schematically shows a cross-section view of a photodetector according to an embodiment of the present disclosure. A photodetector 400 comprises an Si substrate 402, and a BOX layer 404 comprising Sift stacked on the Si substrate 402. The photodetector 400 also comprises an Si layer stacked on the BOX layer 404. The Si layer includes a lateral pin junction structure which comprises Si and is formed in a lateral direction with respect to the Si substrate 402 (a direction parallel to the Si substrate 402). The lateral pin junction structure comprises at least one pin junction, and a first-conductivity-type region (an “n-Si region” herein) 406 that has been doped to exhibit a first conductivity type (an n type herein), a second-conductivity-type region (a “p-Si region” herein) 408 that has been doped to exhibit a second conductivity type (a p type herein), and an i-Si region 414 positioned between the n-Si region 406 and the p-Si region 408.

The photodetector 400 further comprises a light absorbing layer stacked on the lateral pin junction structure. The light absorbing layer may comprise a compound semiconductor. In this example, the light absorbing layer comprises an i-Ge layer 416. As shown in the figure, the lateral pin junction structure and the light absorbing layer may form a rib-shaped waveguide structure. In addition, at least part of an upper part of the light absorbing layer is doped to exhibit a first conductivity type. The whole upper part of the light absorbing layer may be doped to exhibit the first conductivity type, or a part of the upper part only of the light absorbing layer may be doped. In an example, a GeSi layer (n-Ge₁₋ₓSiₓ layer 422, wherein 0<x<1), wherein at least part thereof has been doped to exhibit the first conductivity type (an n type herein), may be formed on the i-Ge layer 416. That is, the light absorbing layer may be constructed to include such a GeSi layer, in addition to the i-Ge layer 416. In the other example, the light absorbing layer may comprise a layered structure including the Ge₁₋ₓSiₓ layer 422 and a Si layer (this can be referred to as a Si cap layer) stacked on the Ge₁₋ₓSiₓ layer 422, in addition to the i-Ge layer 416. At least part of the upper part of a light absorbing layer, such as that explained above, may be doped to exhibit the first conductivity type.

Further, at least part of a side wall of the light absorbing layer is doped to exhibit the first conductivity type, for making the at least part of the upper part of the light absorbing layer to be electrically connected to the region of the first conductivity type (the n-Si region 406 herein) in the lateral pin junction structure. The whole side wall face of the light absorbing layer may be doped to exhibit the first conductivity type, or a part of the side wall only of the light absorbing layer may be doped. In an example, a GeSi layer (n-Ge₁₋ₓSiₓ layer 422, wherein 0<x<1), wherein at least part thereof has been doped to exhibit the first conductivity type (an n type herein), may be formed on the side wall of the i-Ge layer 416. In the other example, the light absorbing layer may comprise a layered structure including the Ge₁₋ₓSiₓ layer 422 and a Si layer stacked on the Ge₁₋ₓSiₓ layer 422, in addition to the i-Ge layer 416. At least part of the side wall of a light absorbing layer, such as that explained above, may be doped to exhibit the first conductivity type.

As shown in FIG. 4, the side wall of the light absorbing layer may be configured in such a manner that it is arranged to be slanted, rather than arranged to be vertical to the Si substrate 402.

In the lateral pin junction structure, the i region (the i-Si region 414) is arranged in a position that is offset, from a center of the light absorbing layer in a lateral direction, in a direction toward the first-conductivity-type region (the n-Si region 406 herein) in the lateral pin junction structure. The Si layer stacked on the BOX layer 404 further comprises an n+-Si region 410 that has been high-concentration-doped to exhibit the first conductivity type (an n type herein), and a p+-Si region 412 that has been high-concentration-doped to exhibit the second conductivity type (a p type herein). The n+-Si region 410 is electrically connected to a metal electrode 418A via a wiring line 413. The p+-Si region 412 is electrically connected to a metal electrode 418B via a wiring line 415. The metal electrodes 418A and 418B may comprise Ti/Al, for example.

The photodetector 400 may further comprise a cladding layer 420 which comprises SiO₂ stacked on the above-explained respective components.

The above-explained photodetector 400 can be constructed by using a silicon photonics technique.

In an example, at least part of the light absorbing layer may be buried in the Si layer stacked on the BOX layer.

In an example, in an interface between the light absorbing layer and the lateral pin junction structure, the light absorbing layer may be doped to exhibit the first conductivity type or the second conductivity type. For example, at least part of a lower face of the i-Ge layer 416 may exhibit the first conductivity type (an n type herein). For example, a part of the quantity of phosphorus used for doping the n-Si region 406 in the lateral pin junction structure may be diffused in the i-Ge layer 416. In the other example, at least part of a lower face of the i-Ge layer 416 may exhibit the second conductivity type (a p type herein). For example, a part of the quantity of boron used for doping the p-Si region 408 in the lateral pin junction structure may be diffused in the i-Ge layer 416.

In the photodetector 400, the light absorbing layer may be optically coupled to an optical waveguide that is formed by the Si layer stacked on the BOX layer 404. In such a case, the photodetector 400 is configured to receive an optical signal from the optical waveguide. Alternatively, the photodetector 400 may be configured to receive an optical signal entering from a part above or below the light absorbing layer.

In an example, the light absorbing layer may be configured to have a thickness that has been set for improving a light absorption rate by optical resonance effect. For example, the thickness T of the light absorbing layer and the center wavelength λ of the optical signal entering the photodetector 400 may roughly satisfy the relationship 2T=N*λ.

The inventor of the subject application has performed simulation relating to the photodetector 400 shown in FIG. 4 according to the present disclosure.

Main numerical values used in the simulation are as follows:

Width of n-Si region 406: 800 nm

Width of p-Si region 408: 1200 nm

Width of i-Si region 414: 300 nm

Width of n+-Si region 410: 2000 nm

Width of p+-Si region 412: 2000 nm

Width of bottom face of i-Ge layer 416: 600 nm

Width of n+-Si/n+-Ge layer 422: 100 nm

Distance of offset of i-Si region 414 with respect to center of light absorbing layer in lateral direction: 400 nm

Thickness of p+-Si region 412 and n+-Si region 410: 90 nm

Distance between upper face of BOX layer 404 and lower face of i-Ge layer 416: 200 nm

Thickness of i-Ge layer 416: 300 nm

Doping concentration in n-Si region 406: 1*10¹⁹/cm³

Doping concentration in p-Si region 408: 1*10¹⁹/cm³

Doping concentration in n+-Si region 410: 2*10²¹/cm³

Doping concentration in p+-Si region 412: 2*10²¹/cm³

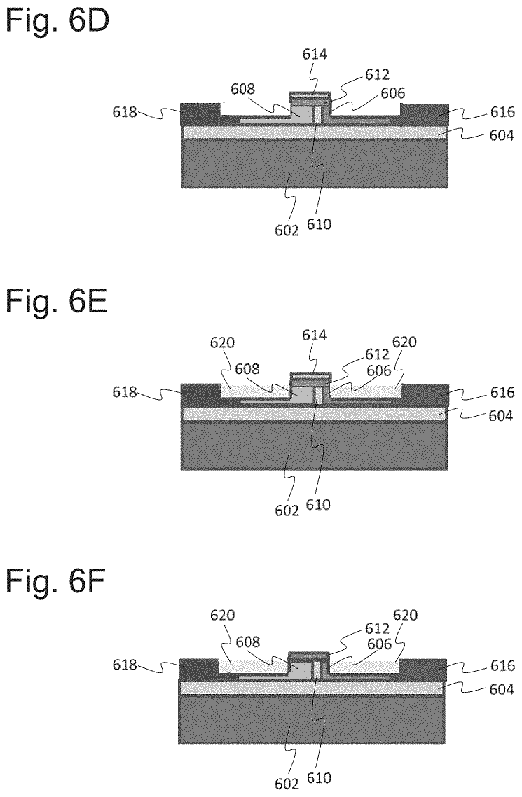

FIG. 5 shows result of simulation, with respect to optical electric field intensity distribution, in the photodetector 400 in the case that the input light power is set to 0 dBm. It can be understood that the value of the optical electric field intensity is approximately the maximum throughout the whole light absorbing layer.

Based on the above computation result, it can be understood, compared with a prior-art photodetector, that the optical electric field intensity in the light absorbing layer is maintained to be high, even if input light power is increased, in the case of the photodetector 400 according to the embodiment of the present disclosure. Thus, the photodetector 400 has an improved high-speed characteristics, and can be used in various kinds of application such as that in middle-range optical communication and long-range optical communication wherein it is assumed that input light power is much higher, and so on, in addition to application in short-range optical communication within a data center.

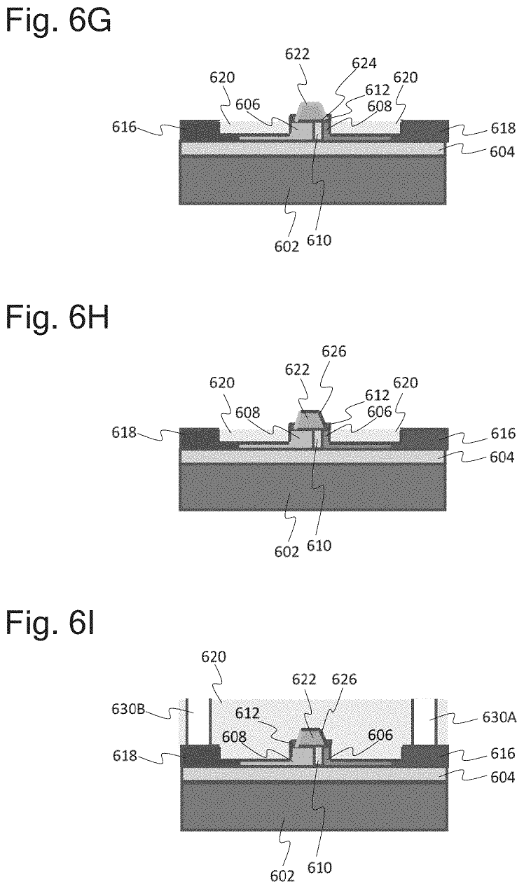

FIGS. 6A-6J are those for explaining a method for manufacturing the photodetector 400 according to the embodiment of the present disclosure.

FIG. 6A shows a cross-section view of an SOI substrate which is used for constructing the photodetector 400. A BOX layer 604 is stacked on a Si substrate 602. For reducing a high-frequency-signal loss, the BOX layer may be designed to have a thickness that is equal to or greater than 1000 nm. A Si layer having a thickness of approximately 100-1000 nm is stacked on the BOX layer 604. In a part of the Si layer, a surface layer is doped by phosphorus by performing an ion implantation method or the like. In another part of the Si layer, a surface layer is doped by boron. Thereafter, by applying a heat treatment, an n-Si region 606 which exhibits the first conductivity type and a p-Si region 608 which exhibits the second conductivity type are constructed. An i-Si region is constructed between the n-Si region 606 and the p-Si region 608. As a result, the electric field intensity in the light absorbing layer is made to be large, and a photodetector which makes it possible to perform high-speed operation can be realized.

Next, as shown in FIG. 6B, as a mask used for forming a rib-shaped waveguide structure including the light absorbing layer, a layered structure comprising an oxide-film mask 612 and a SiNₓ hard mask 614 is formed. The layered structure is subjected to patterning that is performed by using UV lithography, dry etching, or the like.

Next, as shown in FIG. 6C, by using the SiNₓ hard mask 614 and the oxide-film mask 612 as masks, the Si layer comprising the n-Si region 606 and the p-Si region 608 is subjected to patterning, and the rib-shaped waveguide structure is constructed thereby.

Next, as shown in FIG. 6D, in the n-Si region 606, a part having a height equivalent to that of the rib-shaped waveguide structure is high-concentration-doped by phosphorus by performing an ion implantation method or the like. Further, in the p-Si region 608, a part having a height equivalent to that of the rib-shaped waveguide structure is high-concentration-doped by boron by performing an ion implantation method or the like.

Next, as shown in FIG. 6E, an oxide cladding 620 is stacked, for performing selective epitaxial growth of a Ge₁₋ₓSiₓ/Si layered film which will be explained later. At the time, by planarization by using a CMP (chemical mechanical polishing) method, an opening process for selective epitaxial growth of the Ge₁₋ₓSiₓ/Si layered film can be facilitated.

Next, as shown in FIG. 6F, the SiNₓ hard mask 614 is removed by applying a heat phosphoric acid treatment or the like.

Next, as shown in FIG. 6G, an opening 624 for selective epitaxial growth of the Ge₁₋ₓSiₓ/Si layered film is formed on the oxide-film mask 612, by dry etching, a hydrofluoric acid treatment, or the like. Thereafter, the selective epitaxial growth process is applied to the Ge₁₋ₓSiₓ/Si layered film 622.

Next, as shown in FIG. 6H, the Ge₁₋ₓ/Si layered film 622, that has been grown through the selective epitaxial growth process, is doped by phosphorus, and a first-conductivity-type layer 626 is formed on an upper part and a side wall of the Ge₁₋ₓSiₓ/Si layered film 622. The formed first-conductivity-type layer 626 is electrically connected to the n-Si region 606.

Next, as shown in FIG. 6I, an oxide cladding 620 of approximately 1μm is further stacked. Further, a contact halls 630A and 630B are formed for first and second electric contacts, by performing a dry etching method or the like.

Finally, as shown in FIG. 6J, a metal layer such as Ti/TiN/Al(Cu), Ti/TiN/W, or the like is deposited by using a sputtering method, a CVD method, or the like. By performing the process of patterning a metal layer by applying reactive etching, electrode wiring lines 632A and 632B are formed. The photodetector is electrically connected to a driver circuit by using the electrode wiring lines 632A and 632B.

In addition to the structure explained with reference to FIG. 1, a photodetector comprising a longitudinal pin junction structure has been suggested. Such a photodetector comprises a p-Si layer, i-Ge layer, and an n-GeSi layer which are stacked in a direction vertical to a Si substrate. In this case, since it is necessary to construct metal electrodes on the GeSi layer, the manufacturing process thereof is not simple. Further, since it is necessary to construct metal electrodes on the GeSi layer, the width of the i-Ge layer cannot be reduced. Thus, the electric capacity thereof becomes large, so that it becomes difficult to perform high speed operation.

On the other hand, a photodetector according to an embodiment of the present disclosure can be manufactured according to the above method, and metal electrodes can be constructed on the Si layer. Thus, the manufacturing process thereof is simpler, compared with that for a photodetector comprising the above-explained longitudinal pin junction structure.

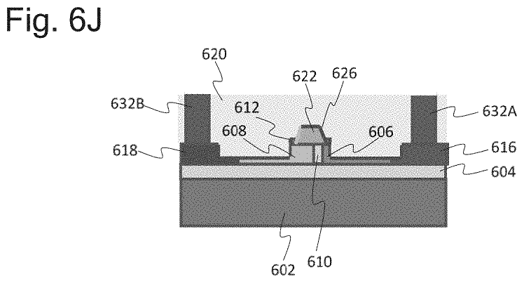

FIG. 7 schematically shows a cross-section view of a photodetector according to an embodiment of the present disclosure. A photodetector 700 is configured to receive an optical signal from a part above or below a light absorbing layer. Similar to the photodetector 400 shown in FIG. 4, the photodetector 700 may comprise a Si substrate 702, a BOX layer 704, an n-Si region 706, a p-Si region 708, an i-Si region 714, an n+-Si region 710, a p+-Si region 712, an i-Ge layer 716, metal electrodes 718A and 718B, a cladding layer 720, and an n-Ge₁₋ₓSiₓ layer 722. The width of the light absorbing layer of the photodetector 700 is wider, compared with the width of the light absorbing layer of the photodetector 400; so that photodetector 700 can receive, efficiently, an optical signal entering from a part above or below thereof.

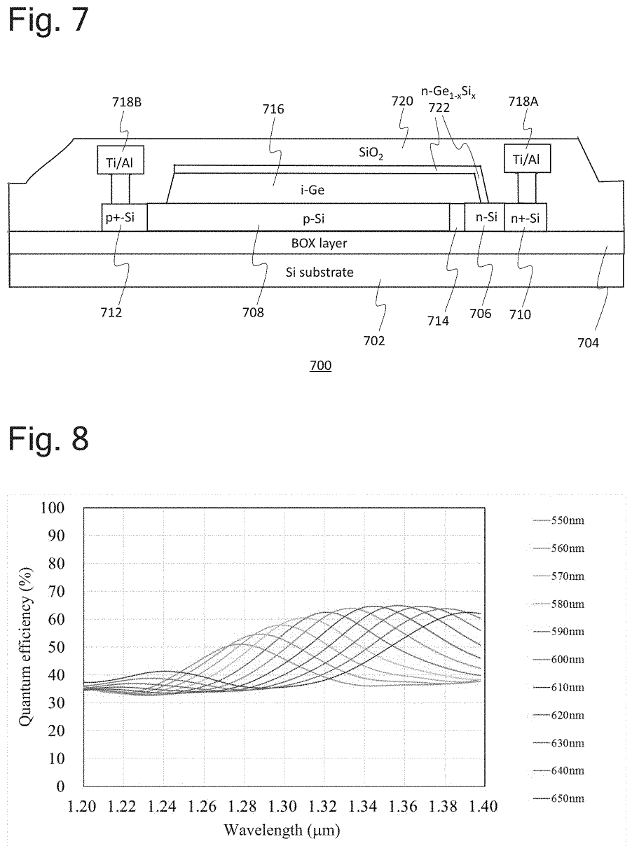

FIG. 8 shows result of computation, with respect to wavelength dependency of quantum efficiency of the photodetector disclosed in FIG. 7, when the thickness of the Ge layer which is the light absorbing layer is used as a parameter. It has become clear that the optical resonance wavelength in the Ge layer changes when the thickness of the Ge layer is changed from 550 nm to 650 nm, and that the quantum efficiency of equal to or greater than 60% can be obtained by optimizing the thickness of the Ge layer according to an optical wavelength to be used.

In the above-explained embodiment, it is supposed that the first conductivity type is an n type and the second conductivity type is a p type. In this regard, it would be understood by a person skilled in the art that a photodetector according to an embodiment of the present disclosure can be obtained even in the case that the first conductivity type is a p type and the second conductivity type is an n type.

Although the embodiments of the present disclosure have been explained in the above description, it should be understood that the embodiments are mere examples, and are not those used for limiting the scope of the present disclosure. It should be understood that changing of, addition of a construction to, and/or modification for improvement of the embodiments can be made without departing from the gist and scope of the present disclosure. The scope of the present disclosure should not be limited by any of the above-explained embodiments, and should be defined by the claims and equivalents thereof only.

1. A photodetector comprising:
a Si layer including a lateral pin junction structure, and
a light absorbing layer stacked on the lateral pin junction structure; and
characterized in that
at least part of an upper part of the light absorbing layer is doped to exhibit a first conductivity type; and at least part of a side wall of the light absorbing layer is doped to exhibit the first conductivity type, for making the at least part of the upper part of the light absorbing layer to be electrically connected to a region of the first conductivity type in the lateral pin junction structure.

2. The photodetector according to claim 1, characterized in that an i region in the lateral pin junction structure is arranged in a position offset from a center of the light absorbing layer in a lateral direction, toward the first-conductivity-type region in the lateral pin junction structure.

3. The photodetector according to claim 1, characterized in that it comprises metal electrodes that are electrically connected to a region, that has been high-concentration-doped to exhibit the first conductivity type, in the Si layer and a region, that has been high-concentration-doped to exhibit a second conductivity type, in the Si layer, respectively.

4. The photodetector according to claim 1, characterized in that the light absorbing layer has a layered structure comprising a GeSi layer and a Si cap layer.

5. The photodetector according to claim 1, characterized in that at least part of the light absorbing layer is buried in the Si layer.

6. The photodetector according to claim 1, characterized in that, in an interface between the light absorbing layer and the lateral pin junction structure, the light absorbing layer is doped to exhibit the first conductivity type or the second conductivity type.

7. The photodetector according to claim 1, characterized in that the lateral pin junction structure comprises at least one pin junction.

8. The photodetector according to claim 1, characterized in that the light absorbing layer comprises a compound semiconductor.

9. The photodetector according to claim 1, characterized in that the light absorbing layer is optically coupled to an optical waveguide constructed by use of the Si layer, and is configured to receive an optical signal from the optical waveguide.

10. The photodetector according to claim 1, characterized in that the photodetector receives an optical signal directed toward the light absorbing layer from up above or down below the light absorbing layer.

11. The photodetector according to claim 1, characterized in that the light absorbing layer has a thickness that has been set for improving a light absorption rate by optical resonance effect.

12. The photodetector according to claim 1, wherein the lateral pin junction structure and the light absorbing layer form a rib-shaped waveguide structure.

13. The photodetector according to claim 1,
wherein the first conductivity type is a p type or an n type.

14. The photodetector according to claim 1, wherein the Si layer is formed on a buried oxide film layer stacked on a Si substrate.
